(19) United States
(12) Patent Application Publication
(10) Pub. No.: US 2005/0175044 A1
(43) Pub. Date: Aug. 11, 2005

(54) Tuneable laser

(76) Inventors: Nick Zakhleniuk, Colchester (GB); Anthony Holden, Brackley (GB)

Correspondence Address: LAHIVE & COCKFIELD, LLP., 28 STATE STREET, BOSTON, MA, 02109, US

(21) Appl. No.: 10/508,386

(22) PCT Filed: Mar. 19, 2003
(86) PCT No.: PCT/GB03/01175

(30) Foreign Application Priority Data
Mar. 19, 2002 (GB) 0206441.8
Mar. 27, 2002 (GB) 0207164.5
May 15, 2002 (GB) 0211039.3
May 15, 2002 (GB) 0211038.5

(51) Int. Cl. H01S 3/10; H01S 5/00

(52) U.S. Cl. 372/20; 372/96; 372/43.01

(57) ABSTRACT

A tuneable laser including a light creating section to generate light and a tuneable section formed of a semiconductor material which utilises the electro-optic effect to achieve a change in the refractive index of the material, Δn, under the influence of an applied field, F, in accordance with the equation: Δn=−½n₀³[rF+sF²]≡Δn_{L}+Δn_{Q}, where nₒ is the refractive index at zero field and Δn_{L} and Δn_{Q} are the linear and quadratic contributions to the change in refractive index respectively, r is the linear electro-optic coefficient of the material and s is the quadratic electro-optic coefficient of the material, the tuning section including a waveguide and the material of the waveguide incorporating a plurality of quantum dots and operating in a wavelength region where the value of rF is sufficiently greater than the value of sF², so as to operate with the dominant effect on Δn being contributed by the linear effect.

This invention relates to tuneable lasers and has particular reference to such tuneable lasers having a tuneable portion incorporating quantum dots.

### BACKGROUND TO THE INVENTION

In this specification the term “light” will be used in the sense that it is used in optical systems to mean not just visible light but also electromagnetic radiation having a wavelength between 800 nanometres (nm) and 3000 nm.

Single wavelength lasers are important for a number of applications in optical telecommunications and signal processing applications. These include multiple channel optical telecommunications networks using wavelength division multiplexing (WDM). Such networks can provide advanced features, such as wavelength routing, wavelength conversion, adding and dropping of channels and wavelength manipulation in much the same way as in time slot manipulation in time division multiplexed systems. Many of these systems operate in the C- and L-Bands in the range 1530 to 1610 nm.

Tuneable lasers for use in such optical communications systems, particularly in connection with the WDM telecommunication systems, are known. A known tuneable system comprises stacks of single wavelength distributed Bragg reflectors (DBR) lasers, which can be individually selected, or tuned over a narrow range, or by a wide tuning range tuneable laser that can be electronically driven to provide the wavelength required.

In all of these tuneable lasers, reliance is placed on altering the refractive index of the tuning element of the laser by an external action to enable different wavelengths of the laser to be selected to satisfy the necessary lasing conditions. Three main methods of varying the refractive index have been proposed and used. In one method, the free electron plasma effect can be used by free carrier injection, that is by passing an electric current through the tuning section. In a second method, the fundamental band-gap can be changed by thermal heating. In a third method electro-refraction modification can be brought about using the electro-optic effect. In the latter case, an electrical field is established across the tuning section, which changes the refractive index of the section and thus alters the wavelength of the light as it passes through the tuning section.

Each of the tuning systems has advantages and drawbacks. In particular the thermal tuning scheme is very slow, the current tuning scheme has its speed limited by thermal heating effects and the electro refraction scheme has limited bandwidth of modulation, and large output power variation.

Preferably all tuning should be fast, it should consume as little energy as possible and it should provide as broad wavelength tuning as possible, ideally covering the C- and the L-bands without the output power variation. In the current injection tuning mechanism, the refractive index is modified through the change of the electronic contribution to the dielectric function due to the injection current. At the same time, the injected current creates Joule heating, which dissipates in the device active region. As a result of this, the real wavelength switching speed of the laser device will be determined by the relatively long characteristic time of the heat dissipation, rather than by the electric current switching speed. The thermal dissipation effects can be decreased through device optimisation but cannot be eliminated. The thermally induced band-gap change has similar limitations.

The use of the electro-optic effect relies on the applied voltage rather than injected current and avoids excess heating and long thermal time constants. However, the low refractive index change available in technologically suitable materials, e.g. GaAs and other III-V semiconductors, is the main obstacle to its practical utilisation.

In recent years a great deal of interest has been shown, both theoretically and practically, in quantum well, quantum wire, and quantum dot containing materials. However, there is as yet no universally accepted and adopted nomenclature for these types of materials, for example these types of materials are sometimes referred to as low dimensional carrier confinement materials and other terms are also used. For clarity, therefore, in this specification there will be used three defined terms: quantum wells, which will, be referred to as QWs; quantum wires; and quantum dots, which will be referred to as QDs.

In this specification the term QW is used to mean a material having a layer of narrow band-gap material sandwiched between layers of wide band-gap material, with the layer of the narrow band-gap material having a thickness d, of the order of the de Broglie wavelength λ_{dB} and the other two dimensions d_{y} and d_{z} of the layer of narrow band-gap material being very much greater than λ_{dB}. Within such a structure, the electrons are constrained in the x dimension but are free to move in the y and z dimensions. Typically for a III-V As based material the thickness of the layer for a QW material would be in the range ˜50 Å to ˜300 Å.

If now the thickness of the layer dₓ is reduced to a minimum to give the QW effect, then there is only room in the QW for one energy level for the electrons. An overall QW may have some regions of one energy level only and some regions of a few energy levels.

If the QW is now considered as having a second dimension, say d_{y}, cut down to the size ˜λ_{dB}, so that both dₓ and d_{y} are ˜λ_{dB} and only d_{z} is very much greater than λ_{dB}, then the electrons are constrained in two dimensions and thus there is, in effect, created a line in which the electrons can freely move in one dimension only, and this is referred to herein as a quantum wire.

If now the quantum wire is further constrained so that d_{z} is also ˜λ_{dB}, then the electrons are constrained within a very small volume and have zero dimension to move in. This is called herein a quantum dot (QD).

Thus if dₓ, d_{y}, and d_{z} are all very much greater than Δ_{dB} the material is simply considered as a bulk material with no quantum effects of the type discussed herein. If dₓ˜λ_{dB} there is provided a quantum well, QW. If dₓ, d_{y}˜λ_{dB}, there is provided a quantum wire, and if dₓ, d_{y}, and d_{z}˜λ_{dB}, then there is provided a quantum dot, QD.

The technology for producing QWs is well known but quantum wires have yet to be produced on a commercial scale. In practise they have been formed in the laboratory by electrically constraining a QW structure with electrical fields or by so-called V-growth, but these are not yet practical commercially available processes.

The present invention is concerned with the use and application of QD materials in tuneable lasers. Production processes for QD materials are well established. Two main processes have been developed, chemical etching and self-assembly, and the self-assembly process will be explained in more detail below.

QD materials have been widely suggested for use in lasers, see for example D Bimberg et al, Novel Infrared Quantum Dot Lasers: Theory and Reality, phys. stat. sol. (b) 224, No. 3, 787-796 (2001). Principally they have been suggested for use in the light creating lasing section of a current injection laser because they can produce light of a very narrowly defined wavelength, with a very low threshold current and QD materials have a very high characteristic temperature so as to give a temperature stable laser emitter. Because of these very significant benefits, most of the work on QD materials in laser applications has concentrated on their use in the emitter.

### APPLICATIONS OF THE INVENTION

The present invention is not directed to the use of QD materials in laser emitters, but is directed to the use of QD materials in the tuning section of a tuneable laser.

The essence of the present invention is the enhancement of the linear electro-optic (LEO) coefficient in a bulk semiconductor material that forms a tuneable section of a tuneable laser, and especially in III-V semiconductors (e.g. GaAs), by the use of quantum dots. The LEO coefficient can be regarded as a means of varying the refractive index (RI) of the material under the effect of an electrical field normally created by an applied voltage.

In bulk III-V semiconductors, the LEO coefficient at optical wavelengths depends on the distortion, (i.e. polarisation) of the tightly bound core electrons in the semiconductor atoms on the application of an electric field. These are strongly bound and the effect is proportionately weak. This leads to the need for high drive voltages and long active regions to build a large enough phase change and effect modulation. Notably, the weakly bound valence electrons do not contribute significantly because they form a conduction band and flow away when a field is applied and do not add to the local dipole moment or polarisation.

QDs are little boxes of narrow band-gap material formed inside the bulk III-V material. They confine these weakly bound electrons and their corresponding holes (in the valence band) and do not allow them to conduct. They are, in essence, artificial atoms. When a field is applied these weakly bound carriers contribute a large dipole moment, or polarisation and hence a large LEO coefficient. In addition the shape of the quantum boxes also leads to a built-in dipole moment before the field is applied and this enhances the LEO coefficient further. Initial results obtained by using the invention show that the LEO coefficient in the dot system is enhanced over the bulk GaAs system by around 200 times (see below).

Even allowing for the reduced overlap of the light field in the dilute layers of dots (compared to the bulk material) this still leaves a factor of at least 5 or 6 in the net effect. The effect can be further enhanced using a plurality of layers of self assembled quantum dots.

In general there are two contributions to the refractive index change, Δn, under an applied electric field F: the linear contribution due to the Pockels effect and quadratic contribution due to the Kerr effect. These are represented in the equation:
Δn=−½nₒ³[rF+sF²]≡Δn_{L}+Δn_{Q} (1)
where r is the linear and s the quadratic electro-optic coefficient, F is the applied field, and nₒ is the refractive index of the material at zero field, and Δn_{L} and Δn_{Q} are the linear and quadratic contributions to the change in refractive index respectively.

The invention is particularly concerned with tuneable lasers which exploit the linear part rather than the quadratic part of the electro-optic effect. The quadratic part is strongest at wavelengths near the band-gap but suffers from high absorption and narrow optical bandwidth. The LEO coefficient has a wide optical bandwidth and as it is operated well away from the band-gap there are low losses in addition to the wide bandwidth utilisation.

### BRIEF DESCRIPTION OF THE INVENTION

By the present invention there is provided a tuneable laser including a light creating section to generate light and a tuneable section formed of a semiconductor material which utilises the electro-optic effect to achieve a change in the refractive index of the material, Δn, under the influence of an applied field, F, in accordance with the equation:
Δn=−½n₀³[rF+sF²]≡Δn_{L}+Δn_{Q}
where nₒ is the refractive index at zero field and Δn_{L} and Δn_{Q} are the linear and quadratic contributions to the change in refractive index respectively, r is the linear electro-optic coefficient of the material and s is the quadratic electro-optic coefficient of the material, the tuning section including a waveguide and the material of the waveguide incorporating a plurality of quantum dots and operating in a wavelength region where the value of rF is sufficiently greater than the value of sF², so as to operate with the dominant effect on Δn being contributed by the linear effect.

The invention also provides a tuneable laser including a light creating section to generate light of a wavelength λ and a tuneable section;
the tuneable section being formed of a semi-conducting material incorporating a plurality of quantum dots and exhibiting an electro-optic response thereby to permit variation of the refractive index;
the band-gap of the semiconducting material incorporating the quantum dots being such that the corresponding wavelength λ_{g} is less than λ.

The invention further provides a tuneable laser including a light creating section to generate light of a wavelength λ and a tuneable section including a waveguide;
the waveguide of the tuneable section being formed of a semiconducting material incorporating a plurality of quantum dots and exhibiting an electro-optic response thereby to permit variation of the refractive index;
the band-gap of the semiconducting material incorporating the quantum dots being such that the corresponding wavelength λ_{g} is less than λ.

In another form, the invention provides a tuneable laser including a light creating section to generate light and a tuneable section for adjusting the wavelength thereof within the range λ₁ and λ₂;
the tuneable section being formed of a semiconducting material incorporating a plurality of quantum dots and exhibiting an electro-optic response thereby to permit variation of the refractive index;
the band-gap of the semiconducting material incorporating the quantum dots being such that the corresponding wavelength λ_{g} is less than both λ₁ and λ₂ by an amount sufficient that the change in refractive index at λ₁ and λ₂ is substantially the same.

In yet a further form, the invention provides a tuneable laser including a light creating section to generate light and a tuneable section for adjusting the wavelength thereof within the range λ₁ and λ₂;
the tuneable section including a waveguide, the waveguide of the tuneable section being formed of a semiconducting material incorporating a plurality of quantum dots and exhibiting an electro-optic response thereby to permit variation of the refractive index;
the band-gap of the semiconducting material incorporating the quantum dots being such that the corresponding wavelength λ_{g} is less than both λ₁ and λ₂ by an amount sufficient that the change in refractive index at λ₁ and λ₂ is substantially the same.

In this way, a device with a wide bandwidth is achieved by appropriately separating the band-gap wavelength and the operating wavelengths. As the separation increases, the slope of the linear effect with wavelength decreases and thus the difference in refractive index (which leads to dispersion) at λ₁ and λ₂ decreases. Experimental results for GaAs material given in “Analysis and Design of High-Speed High Efficiency GaAs—AlGaAs Double Heterostructure Waveguide Phase Modulator”, Sang Sun Lee, Ramu V. Ramaswany and Veeravana S. Sundaram, IEEE journal of Quantum Electronics, Vol. 27, No. 3, March 1991, suggests that in the dominant linear effect region the variation of the linear effect term Δn_{L}, is less than 0.1% per nanometre of wavelength change when operating in the range of wavelengths covering the telecommunication C and L-Bands (substantially 1530 nm to 1610 nm). By comparison the same data suggests that in this wavelength region the variation of the quadratic effect term Δn_{Q}, is greater than 1% per nanometre of wavelength change. To give a useful operating bandwidth, it is further preferred that the difference between λ₁ and λ₂ is greater than 1 nm.

The tuneable section may be the tuning section of the laser, and may incorporate a distributed Bragg reflector.

The tuneable laser may incorporate a phase change section and the phase change section may be a tuneable section.

The semiconductor material may be a III-V semiconductor material, which may be based on a system selected from the group GaAs based, InAs based materials and InP-based materials.

The band-gap wavelength λ_{g} of the quantum dots may be smaller than the wavelength (λ) of the photons emitted by the light creating section. It is preferred that the band-gap wavelength λ_{g} is separated from the operating wavelength(s) of the laser. Thus, the band-gap wavelength λ_{g} is typically 100 nm shorter than the wavelength of the photons emitted by the light creating section. This avoids considerable absorption of the light in a tuning section. Other suitable separations are achieved if λ_{g} is less than 90% of λ and/or if λ_{g} is less than 1400 nm in which case normal optical signals in the region of 1550 nm are suitably separated.

The laser may comprise a combination of gain sections, phase sections and tuning sections and thereby be a three or four section laser, or have more than four sections.

The quantum dots may be self-assembled quantum dots in which the self-assembled quantum dots may be formed of InAs based material in host GaAs based semiconductor material. The host material may be formed on a GaAs substrate.

The self-assembled quantum dots may be formed of InGaAs based material in host GaAs based semiconductor material which host material may be formed on a GaAs substrate.

The self-assembled quantum dots may be formed of InAs based material in host InGaAsP based semiconductor material which host material may be formed on an InP substrate.

The self-assembled quantum dots may be formed of InGaAs based material in host InₓGa₁₋ₓAs_{y}P_{1-y} based semiconductor material which host material may be formed on an InP substrate.

Alternatively, the quantum dots may be formed by a chemical etching process.

There may be a plurality of layers of quantum dots.

### DESCRIPTION OF THE PREFERRED EMBODIMENTS OF THE INVENTION

The present invention will now be described with reference to the accompanying drawings, of which:—

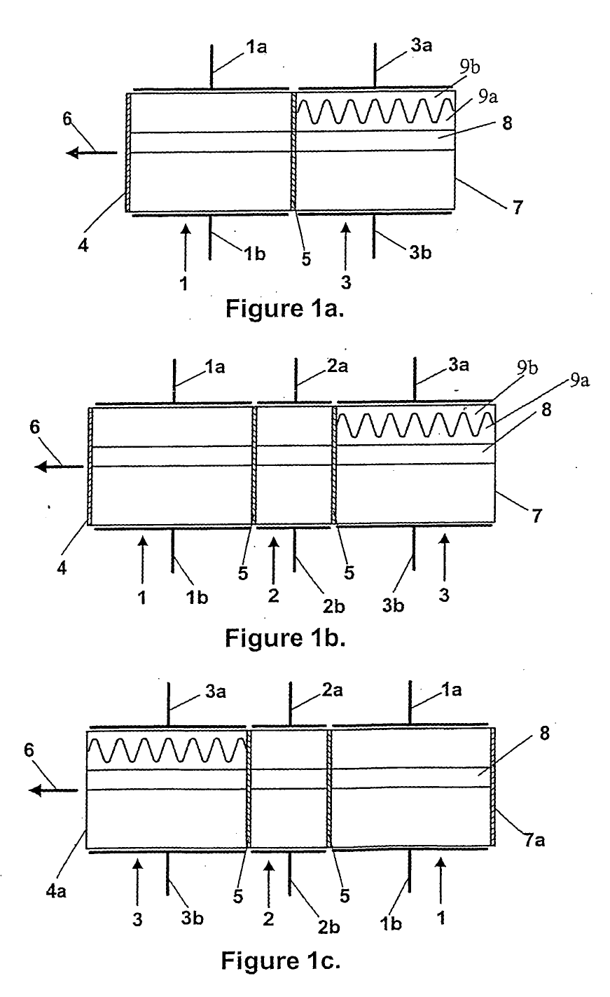

FIG. 1a. is a schematic cross section of a two section tuneable laser

FIG. 1b. is a schematic cross section of a three section tuneable laser

FIG. 1c. is a schematic cross section of an alternative three section tuneable laser, and

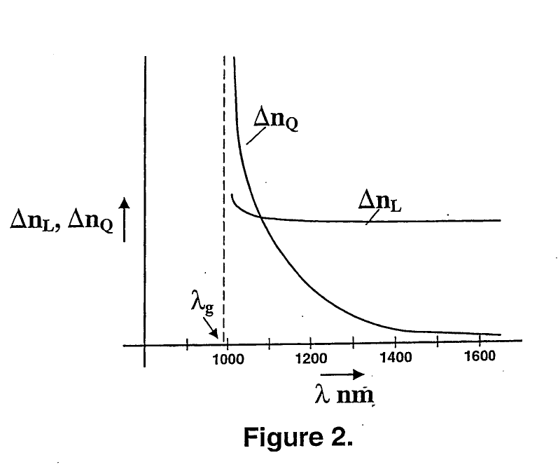

FIG. 2. is a schematic graph of the values Δn_{L} and Δn_{Q} against wavelength λ.

Semiconductor tuneable lasers are known in the art. The principals of tuneable lasers are described in chapters 4 and 5 of “Tuneable Laser Diodes”, by Markus-Christian Amann and Jens Bus, ISBN 0-89006-963-8, published by Artech House, Inc.

Referring to FIG. 1a., this shows schematically in cross section a first embodiment two-section Distributed Bragg Reflector (DBR) tuneable laser, which can be used to demonstrate how the invention can be put into effect.

The laser comprises a gain section 1, and a tuning section 3 incorporating a DBR grating. At the front of the gain section on the opposite side to the tuning section is a partially reflecting mirror 4, which reflects at all operating wavelengths. The laser works by injecting current through an electrode 1a into the gain section 1 and through a return electrode 1b to create the carrier population inversion and cause the gain section to emit light. This light is reflected by the tuning section 3, which reflects at the lasing wavelength, and by the mirror 4, so as to build up into laser light at the wavelength of the reflection from the DBR grating, in a manner well known per se. The laser light is emitted from the front of the laser in the direction of the arrow 6. A common optical waveguide 8 operates across the whole longitudinal lasing cavity of the device. The rear facet 7 of the laser is anti-reflection coated so that it does not produce any secondary reflections which would disturb the desired operation of the longitudinal lasing cavity formed between the tuning section and the front mirror 4. Typically a tap of laser light from the rear facet 7 may be used in wavelength locker applications. Electrical isolation between sections 1 and 3 is achieved by an electrical barrier 5, which is optically transparent so as not to add any appreciable attenuation within optical waveguide 8. A suitable means of constructing such a barrier is given in “Ultra-Fast Optical Switching Operation of DBR Lasers using an Electro-Optical Tuning Section”; F Delorme, A Ramdane, B Rose, S Slempkes and H Nakajima; IEEE Photonics Technology Letters, Volume 7, No. 3, p. 260, March 1995.

The DBR grating within tuning section 3 is preferably formed between a layer of material 9a of a refractive index n₂ and an upper layer of material 9b having a refractive index n₃ which is lower than the refractive index n₂ of the layer 9a. The refractive indices n₂ and n₃ are both lower than refractive index n₁ of the waveguide 8. The DBR grating itself is defined by a boundary between the two layers 9a and 9b. It is formed by laying down layer 9a upon waveguide layer 8, photo-etching the layer 9a in the manner well known per se, for example using electron beam writing techniques or phase mask holographic techniques as though it were any other material, and then laying down the upper layer 9b onto the layer 9a which has the DBR grating interface etched into it.

The pitch of the grating formed between layers 9a and 9b can be determined by the Bragg condition.
λ=2n_{eff}Λ
where λ is the wavelength, n_{eff} is the effective refractive index of the waveguide material. In some cases, see below, n_{eff} may not be exactly the same n₁. A is the pitch for first order gratings, which are preferred as they provide the strongest coupling.

As is well known, if a potential is passed via electrode 3a, the effective refractive index of the grating and the active material immediately underneath the electrode is decreased and hence the wavelength of the grating can be tuned.

The tuneable laser shown in FIG. 1a. is in the most basic form. A preferred embodiment is shown in FIG. 1b. Common integers have been used for equivalent functionality for all embodiments described.

FIG. 1b shows schematically in cross section a three-section DBR, tuneable laser. The laser comprises a gain section 1, a phase change section 2 and a tuning section 3 incorporating a DBR grating. At the front of the gain section on the opposite side to the phase change 2 is a partially reflecting mirror 4, which reflects at all operating wavelengths. The laser works by injecting current through an electrode 1a into the gain section 1 and through a return electrode 1b to create the carrier population inversion and cause the gain section to emit light. This light is reflected by the grating in the tuning section 3, which reflects at the lasing wavelength, and by the partially reflecting mirror 4, so as to build up into laser light at the wavelength of the reflection from the DBR grating. The laser light is emitted from the front of the laser in the direction of the arrow 6. The phase matching section 2 is used to maintain a constant longitudinal optical cavity length and thereby prevent mode hoping. The phase section has its own independent electrodes 2a and 2b. Similarly, the tuning section 3 has its own independent electrodes 3a and 3b. As with the two section tuneable laser the three section device includes a longitudinal waveguide 8, rear facet 7, and electrical isolation barriers 5, between each of its sections.

Those of ordinary skill will appreciate that the architecture of FIG. 1b., may be modified to an alternative preferred embodiment as shown in FIG. 1c., wherein the tuning section and gain section have been interchanged. In this architecture the rear facet 7a would be coated for high reflectivity to act as a mirror. In this arrangement the front mirror 4a would be designed for very high transmission and minimal reflectivity so that operationally the cavity defined by 4a and 7a, would be negated by the dynamics of the cavity defined by 7a and the tuning section 3. Each of the sections 1, 2 and 3 in this design have their own independent sets of electrodes 1a, 1b, 2a, 2b, and 3a, 3b respectively.

It will be appreciated that as well as two and three section longitudinal semiconductor tuneable lasers there are other classes of design such as the four section laser discussed in GB2337135B. In the main these higher order tuneable laser design use alternative mirror arrangements in place of the front facet mirror. In so far as these alternative mirror arrangements rely upon the material refractive index to determine the operating wavelength, so this invention may be used with these higher order tuneable laser designs.

With reference to FIG. 1b, a preferred embodiment, to vary the wavelength of light emitted by the laser, a voltage is applied between the electrode 3a and the return electrode 3b, to change the refractive index of the material of the tuning section and to cause it to reflect at a different wavelength. This tuning mechanism is described in “Ultra-Fast Optical Switching Operation of DBR Lasers using an Electro-Optical Tuning Section”; F Delorme, A Ramdane, B Rose, S Siempkes and H Nakajima; IEEE Photonics Technology Letters, Volume 7, No. 3, p. 260, March 1995.

In a similar manner to the electrical drive of the tuning section so the phase section can be electrically driven to make fine tuning control.

The effect of the field established across the tuning section is to vary the refractive index in accordance with equation (1) above:
Δn=−½n₀³[rF+sF²]≡Δn_{L}+Δn_{Q}

However, the values of both r and s are only constant at a given wavelength and the variation in both r and s with wavelength λ is as shown schematically in FIG. 2. It can be seen from this equation that both r and s decrease with increasing wavelength away from the characteristic wavelength λ_{g}, but that the value of s varies very significantly with wavelength whereas the value of r varies only by small amounts with wavelength.

The characteristic wavelength, λ_{g}, is defined as follows. The band-gap is the energy difference ΔE_{g} between the electrons in the valence band and the electrons in the conduction band. If such a material is illuminated with light at a plurality of wavelengths, then light at certain wavelengths will raise the energy of some of the electrons in the valence band and raise them up into the conduction band. If those electrons then fall back into the valence band from the conduction band, they each will emit a photon of a wavelength λ_{g} which is related to the energy difference between the two bands, ΔE_{g}, defined as:
λ_{g}=hC/ΔE_{g}
where h is Planck's constant, and C is the velocity of light in the material. This is referred to as the band-gap wavelength or sometimes the band edge wavelength.

Given that the Δn varies only with the first power of F in the portion of the equation concerned with r (λn_{L} term) but with the square of F in the portion concerned with s (λn_{Q} term), and given that the wavelength λ_{g} corresponds to the band-gap energy for the semiconductor material of the tuning section 3, it can be understood why effort has been focussed on enhancing the electro-optic effect by utilising the quadratic term in equation (1) Δn_{Q}, for example, in light electro-absorption modulators such as described in “Fibre-Optic Communication Systems” by G. P. Agrawal, published by John Wiley and Sons, 1997, page 127, but the penalty is increased light absorption.

Indeed, in all conventional tuneable lasers, including those using current injection tuning, the tuning section always uses material with a band-gap wavelength λ_{g} shorter than the lasing wavelength to overcome the absorption penalty incurred when operating close to the material band-gap wavelength λ_{g}. As a consequence use of the quadratic electro-optic effect in a tuning section of a tuneable laser is particularly disadvantageous because it forces the design of the tuning section material to have λ_{g} very close to the lasing wavelength.

The invention goes completely in the opposite direction and seeks to work in the regions where the linear electro-optic effect r (λn_{L} term) is dominant and significantly above the band-gap wavelength λ_{g}.

However, in all currently known semiconductor bulk materials the linear electro-optic effect is very small and does not yield sufficient change in Δn for all practical implementations. The electro-optic tuning scheme has relied upon use of the quadratic effect only. This has been demonstrated in the experiment described in the paper “Ultra-Fast Optical Switching Operation of DBR Lasers using an Electro-Optical Tuning Section”; F Delorme, A Ramdane, B Rose, S Slempkes and H Nakajima; IEEE Photonics Technology Letters, Volume 7, No. 3, p. 260, March 1995. A tuning range of only 2.5 nm was achieved. Such a small wavelength tuning range was limited by the increase of the absorption losses with increase of applied bias. Although Δn_{Q} could be increased further by increasing the applied bias, it could be achieved only at the expense of a decrease in the output power. For practical telecommunication devices a tuning range in excess of 40 nm is desired without any change of output power across the tuning range.

As shown in FIG. 2., the linear effect (Δn_{L}) is relatively insensitive to wavelength. The linear effect is also not accompanied by the light absorption losses.

To enhance the linear electro-optic effect (LEO) we now consider a QD structure. As mentioned above, this effectively comprises a plurality of small, notionally zero dimension regions, in a host of bulk semiconductor material. These regions are capable of capturing and confining carriers (electrons and/or holes) as described in “Quantum Dot Heterostructures” by D. Bimberg, M. Grundmann and N. N. Ledentsov, published by Wiley, Chichester 1999, chapter 1. The mechanism of electro-optic effect enhancement is described below. Two main methods of producing such structures have been developed and are described in chapter 2 of the above reference. The first is to produce a flat relatively thick layer of bulk wide band-gap material and to deposit on it a thin layer of narrow band-gap material each of appropriately chosen lattice constant and band-gap. The thin layer of narrow band-gap material is then covered with a layer of photo-resist, and exposed to form a pattern of dots. The unwanted material is then chemically etched away and the photo-resist is then stripped off. Another thick layer of bulk material is applied and the process is repeated as often as is required.

A preferred alternative method for forming the QDs is however the self-assembly method (SAQDs) as described in chapter 4 the Bimberg, Grundmann and Ledentsov reference above. In this process a thin layer of, for example, InAs is grown rapidly onto a thick bulk layer of, for example, GaAs. This can be done using either molecular beam epitaxy (MBE) or metal organic vapour phase epitaxy (MOVPE). MOVPE is also sometimes called metal organic chemical vapour deposition (MOCVD).

The amount of the InAs is so controlled as to exceed a critical thickness at which point the grown layer splits into isolated dots as a consequence of the strain between the InAs and the GaAs, of our example, and the growth conditions. These dots can be further overgrown by a further layer of GaAs, and then further InAs dots grown as described. This can be repeated for a plurality of layers. This results in a plurality of layers of individual quantum dots (QD).

MOVPE can be used, as is known, to create QDs on an industrial scale. The QDs are self-assembling and typically contain a few thousand of atoms and are normally very flattened pyramids. The ratio of the pyramid base, d, to their height, h, is normally in the range of 5 to 100. Since they are self-assembling, the dimensions of each dot cannot be separately controlled however, it is known that the average size and density of dots can be controlled technologically and manufactured reproducibly.

We now discuss how such QDs can be used to enhance the linear electro-optic effect. In equation (1) above the linear effect Δn_{L} is mainly associated with the core electrons in bulk material. In a semiconductor, the core electrons stay on the lattice, whilst the valence electrons go off into the conduction band and become conduction electrons if they attain an energy level sufficient to pass across the band-gap. These electrons are free to move throughout the material and provide electrical conduction.

In a QD material the conduction electrons on atoms within a quantum dot cannot get away from the quantum dots, as they cannot attain sufficient energy to overcome the additional confinement energy of the quantum dot. The outer band electrons are confined to the dot and are not free to move through the host semiconductor material and provide electrical conduction.

When an external field is applied to the structure of a semi-conductor, the field distorts the atoms and it is this distortion that actually causes linear variation of the refractive index. In a bulk material the applied field has to interact with the valence electrons, which are strongly bound to the nucleus of the atoms, so the distortion is relatively small. However, in a QD the outer conduction electrons are locked into the dot. The QD behaves like an artificial atom. When an electric field is applied the conduction electrons confined within the QD behave like very loosely bound core electrons. The dot is therefore a very highly polarisable artificial atom. This unique characteristic of quantum dots (QD) distinguishes them over all other bulk, quantum well or quantum wire semiconductor materials.

As a consequence of the above the linear electro-optic effect within a QD layer is much greater than in bulk material. For example, in InAs dots in GaAs the enhancement factor is typically 200 as described in the Journal of Vacuum Science and Technology, B 19 (4) 1455, 2001. Even though current technology permits a packing density such that only 3% of the volume of a structure can be formed of QDs, this still means that the overall increase in the linear effect is 3% of 200, i.e. about six times greater. The effect can be further enhanced by incorporating a plurality of quantum dot layers.

This means that compared to bulk material a QD material would be typically six times or more effective in changing the refractive index via the linear electro-optic effect, for the same bias condition.

It is well known that the bulk of the light passing through the tuneable laser is passing through the waveguide 8. The Bragg grating formed in the tuning section influences only the evanescent tail of the light passing through the laser. Thus it is possible to influence the light passing through the laser by incorporating QDs in either of the layers 9a and 9b between which the Bragg grating is formed or within the waveguide itself. Whichever material has the QDs in it will have a significantly greater change of refractive index under the influence of the electric field, so that the tuning effect, which relies on the overall change to the effective refractive index n_{eff} of the tuning section as a whole, is significantly increased by the provision of the QDs. In this case n_{eff}=n₀+Δn. For maximum effect the QDs should be located in the region of the material where the optical field is strongest. This would normally be at the high refractive index layer in the waveguide structure.

In a practical application with a tuneable semiconductor laser such QD material used in the tuning section would allow the tuneability to be increased to typically six times the wavelength range. This makes the linear electro-optic effect a viable mechanism for tuning a semiconductor laser.

An advantage of using the linear electro-optic effect induced refractive index change is characterised in that a change of wavelength is not accompanied by a change in optical power output. This is because the change in refractive index consequential to the linear electro-optic effect is not accompanied by a change in the absorption coefficients of the light. This is in marked contrast to the case when using the quadratic electro-optic effect to change the refractive index due to its need to work with λ_{g} very close to the lasing wavelength. In this region the absorption varies strongly with applied voltage and output light power will vary across the tuning range as shown in FIG. 2. of paper “Subnanosecond Tuneable Distributed Bragg Reflector Lasers with an Electro-optical Bragg Section”: F Delorme, S Slempkes, A Ramdane, B Rose, H Nakajima, IEEE Journal of Selected Topics in Quantum Electronics, Volume 1, No. 2, p. 396, June 1995. Telecommunication systems require laser sources feeding the system with a constant output light power for each wavelength.

Use of an InP substrate for deposition of InAs quantum dots has been considered as one of the attractive methods in order to grow quantum dots in the gain or light creating and emitting section of a laser emitting at 1.55 μm, as described by A Pouchet, A Le Corre, H L'Haridon, B Lambert and A. Salaum, Applied Physics Letters No. 67, 1850 (1995).

The current tuneable lasers for 1.55 cm are also based on the InP/InₓGa₁₋ₓAs_{y}P_{1-y} material system. Therefore, it is very important from a practical point of view that quantum dots can also be incorporated into the tuneable section(s) of lasers based on the above materials. Although currently there is no experimental evidence to demonstrate growth of InAs quantum dots on the quarternary materials such as for example, InₓGa₁₋ₓAs_{y}P_{1-y}, it is believed that there should not be any technological obstacles s to realise such a growth. This is because the most important parameter for quantum dots growth is a lattice mismatch between InAs and InₓGa₁₋ₓAs_{y}P_{1-y}. Since the InP layer is lattice matched to InₓGa₁₋ₓAs_{y}P_{1-y}, this means that the lattice mismatch between InAs and InₓGa₁₋ₓAs_{y}P_{1-y} is the same as between InAs and InP. Consequently, realisation of the quantum dots growth in the latter system means that they should also be capable of being grown in the former material system.

For chosen compositions in the quarternary alloy InₓGa₁₋ₓAs_{y}P_{1-y} in current tuneable lasers the band-gap wavelength corresponds to 1.42 μm wavelength. Dot containing materials should and could be designed to achieve a similar or shorter band-gap wavelength. All the above can also apply in dots made using InGaAs instead of InAs. Table 1 below summarises the typical combinations that can be used for dots formed in an epitaxially grown host, which surrounds the quantum dots, on a given substrate.

TABLE 1

| Dot Material | Host Material | Substrate Material |
|---|---|---|
| InAs | GaAs | GaAs |
| InGaAs | GaAs | GaAs |
| InAs | InₓGa₁₋ₓAs_{y}P_{1-y} (Quarternary) | InP |
| InGaAs | InₓGa₁₋ₓAs_{y}P_{1-y} (Quarternary) | InP |

In order that optical losses near the band-gap edge are avoided, it is preferred that QDs are used with a band-gap energy larger than the energy of the emitted photons in the gain section. As naturally grown In(Ga)—As/GaAs SAQDs have a band-gap energy corresponding to a wavelength typically of 1200 to 1300 nm, which is far away from the wavelength of 1550 nm used in the telecommunication C-band, this a very suitable system. However, for compatibility with existing InP-based laser diode structures, quantum dots in InP-based materials can also be designed and produced.

Present technology permits the creation of QDs using a wide range of III-V semiconductor materials. This permits the invention to be used in the tuneable section of lasers based on many otherwise unsuitable materials. The number of stacked layers is only limited by the technology available at the time of utilisation of the invention.

As mentioned above and as shown with reference to FIG. 2., the linear effect is relatively independent of the wavelength compared to the quadratic effect. Thus the devices can operate over wide bandwidths when operating in the LEO effect mode, and without detrimental absorption of the light.

The invention thus permits high wavelength tuning speed, a wide tuning range, constant light output power, low energy consumption for switching operation and wavelength holding, substantial elimination of the Joule heating effect as compared to current injection, or thermal, tuning schemes.

Embodiments of tuneable lasers in which QD material is used in the phase sections are possible. In such an embodiment the phase section can be very much shorter, because the refractive index change is much greater, and thus the optical losses through this section can be reduced. Similarly, tuneable laser structures can be envisaged in which the QD material is used for all tuning sections and phase sections such as occur within four section, or higher order, tuneable lasers. QD material may also be used in the gain section of a tuneable laser as is known in the art.

1. A tuneable laser, comprising a light creating section to generate light and a tuneable section formed of a semiconductor material which utilizes the electro-optic effect to achieve a change in the refractive index of the material, Δn, under the influence of an applied field, F, in accordance with the equation:
Δn=−½n₀³[rF+sF²]≡Δn_{L}+Δn_{Q}
where nₒ is the refractive index at zero field and Δn_{L} and Δn_{Q} are the linear and quadratic contributions to the change in refractive index respectively, r is the linear electro-optic coefficient of the material and s is the quadratic electro-optic coefficient of the material, the material incorporating a plurality of quantum dots and operating in a wavelength region where the value of rF is sufficiently greater than the value of sF², so as to operate with the dominant effect on Δn being contributed by the linear effect.

2. A tuneable laser as claimed in claim 1, wherein tuning section comprises a waveguide and the material of the waveguide includes the plurality of quantum dots operating in the wavelength region where the value of rF is sufficiently greater than the value of sF², so as to operate with the dominant effect on Δn being contributed by the linear effect.

3. A tuneable laser as claimed in claim 1, wherein a band-gap wavelength λ_{g} of the quantum dots is shorter than a wavelength of the photons emitted by the light creating section.

4. A tuneable laser as claimed in claim 1, wherein a band-gap wavelength λ_{g} of the quantum dots in the tuneable section is typically 100 nm shorter than the wavelength of the photons emitted by the light creating section.

5. A tuneable laser, comprising a light creating section to generate light of a wavelength λ and a tuneable section;
the tuneable section being formed of a semiconducting material incorporating a plurality of quantum dots and exhibiting an electro-optic response thereby to permit variation of the refractive index;
the band-gap of the semiconducting material incorporating the quantum dots being such that the corresponding wavelength λ_{g} is less than λ.

6. A tuneable laser according to claim 5, wherein the tuneable section comprises a waveguide being formed of the semiconducting material incorporating the plurality of quantum dots and exhibiting the electro-optic response thereby to permit variation of the refractive index.

7. A tuneable laser according to claim 5, wherein the wavelength λ_{g} is less than 1400 nm.

8. A tuneable laser according to claim 5, wherein the wavelength λ_{g} is less than 90% of λ.

9. A tuneable laser according to claim 5, wherein the difference between λ_{g} and λ is greater than 100 nm.

10. A tuneable laser, comprising a light creating section to generate light and a tuneable section for adjusting the wavelength thereof within the range λ₁ and λ₂;
the tuneable section being formed of a semiconducting material incorporating a plurality of quantum dots and exhibiting an electro-optic response thereby to permit variation of the refractive index;
the band-gap of the semiconducting material incorporating the quantum dots is such that a corresponding wavelength λg is less than both λ1 and λ2 by an amount sufficient that the change in refractive index at λ1 and λ2 is substantially the same.

11. A tuneable laser according to claim 10, wherein the tuneable section including a waveguide; being formed of the semiconducting material incorporating the plurality of quantum dots and exhibiting the electro-optic response thereby to permit variation of the refractive index.

12. A tuneable laser according to claim 10, wherein the difference in refractive index at λ₁ and λ₂ is less than 0.1% per nanometre of wavelength change.

13. A tuneable laser according to claim 10, wherein the difference between λ₁ and λ₂ is greater than 1 nm.

14. A tuneable laser as claimed in claim 1, wherein the tuneable section is the tuning section of the laser.

15. A tuneable laser as claimed in claim 14, wherein the tuneable section incorporates a distributed Bragg reflector.

16. A tuneable laser as claimed in claim 15, wherein the distributed Bragg reflector is formed between two layers of different refractive indices and a plurality of quantum dots is provided in either of the layers between which the Bragg grating is formed.

17. A tuneable laser as claimed in claim 1, wherein the tuneable laser incorporates a phase change section and the phase change section is a tuneable section.

18. (canceled)

19. (canceled)

20. A tuneable laser as claimed in claim 1, wherein the laser comprises at least three sections.

21. A tuneable laser as claimed in claim 1, wherein the quantum dots are self-assembled quantum dots.

22. A tuneable laser as claimed in claim 21, wherein the self-assembled quantum dots are formed of one of an InGaAs and an InAs based material in a host GaAs based semiconductor material formed on a GaAs substrate.

23. (canceled)

24. (canceled)

25. (canceled)

26. A tuneable laser as claimed in claim 21, wherein the self-assembled quantum dots are formed of one of an InGaAs and an InAs based material in a host InₓGa₁₋ₓAs_{y}P_{1-y} based semiconductor material formed on an InP substrate.

27. (canceled)

28. (canceled)

29. (canceled)

30. (canceled)

31. A tuneable laser as claimed in claim 1, further comprising a plurality of layers of quantum dots.
